(19) United States
(12) Patent Application Publication
(10) Pub. No.: US 2022/0209154 A1
(43) Pub. Date: Jun. 30, 2022

(54) WHITE LIGHT EMITTING DEVICE AND LIGHT EMITTING DISPLAY DEVICE INCLUDING THE SAME

(71) Applicant: LG DISPLAY CO., LTD., SEOUL (KR)

(72) Inventors: Yong Hwan KIM, Seoul (KR); Ki Woog SONG, Seoul (KR); Ji Hoon KIM, Paju-si (KR); Ji Yun KIM, Seoul (KR)

(73) Assignee: LG DISPLAY CO., LTD., SEOUL (KR)

(21) Appl. No.: 17/560,601

(22) Filed: Dec. 23, 2021

(30) Foreign Application Priority Data
Dec. 31, 2020 (KR) 10-2020-0190031

(51) Int. Cl. H01L 51/50; H01L 27/32

(52) U.S. Cl. CPC H01L 51/504; H01L 51/5016; H01L 27/3244; H01L 51/5072; H01L 51/5056; H01L 27/322

(57) ABSTRACT

A white light emitting device and a light emitting display device including the same, in which the relationship between the triplet energy levels of dopants of emission layers is appropriately adjusted so as to improve the efficiency of the white light emitting device and the light emitting display device, thereby increasing a color temperature and enabling rich color representation.

### CROSS-REFERENCE TO RELATED APPLICATION

This application claims the priority of Korean Patent Application No. 10-2020-0190031, filed on Dec. 31, 2020, which is hereby incorporated by reference in its entirety as if fully set forth herein.

### BACKGROUND

### Field of the Disclosure

The present disclosure relates to a white light emitting device and a light emitting display device including the same. Although the present disclosure is suitable for a wide scope of applications, it is particularly suitable for improving emission efficiency, color temperature, and visibility.

### Description of the Background

A self-emission display device has been considered a competitive application because it does not require a separate light source and enables implementation of a compact device design and vivid color display. The self-emission display device may be classified into an organic light emitting display device and an inorganic light emitting display device depending on the light emitting material therein.

A self-emission display device includes a plurality of subpixels and a light emitting device provided in each of the subpixels, thereby emitting light without a separate light source.

As a display device, a tandem device, which achieves high resolution and high integration and in which multiple stacks are stacked, has recently received increased attention.

### SUMMARY

Accordingly, the present disclosure is to provide a white light emitting device and a light emitting display device including the same, which exhibit improved efficiency, an improved color temperature, and improved visibility.

In the white light emitting device and the light emitting display device including the same according to the present disclosure, the relationship between the triplet energy levels of dopants of emission layers is appropriately adjusted so as to improve the efficiency of the white light emitting device and the light emitting display device, thereby increasing a color temperature and enabling rich color representation.

To this end, a white light emitting device according to an aspect of the present disclosure may include a first electrode and a second electrode disposed opposite each other on a substrate, a first stack disposed between the first electrode and a first charge generation layer, the first stack including a first emission layer including a first blue dopant, and a second stack disposed between the first charge generation layer and the second electrode, the second stack including a second emission layer including a red dopant, a third emission layer including a yellowish-green dopant, and a fourth emission layer including a green dopant. The first blue dopant may have a triplet energy level equal to or higher than the triplet energy level of the green dopant.

A light emitting display device according to an aspect of the present disclosure may include a substrate including a plurality of subpixels, a first electrode provided in each of the plurality of subpixels on the substrate, a second electrode provided over the plurality of subpixels so as to be opposite the first electrode, a first stack disposed between the first electrode and a first charge generation layer over the plurality of subpixels, the first stack including a first emission layer including a first blue dopant, and a second stack disposed between the first charge generation layer and the second electrode over the plurality of subpixels, the second stack including a second emission layer including a red dopant, a third emission layer including a yellowish-green dopant, and a fourth emission layer including a green dopant. The first blue dopant may have a triplet energy level equal to or higher than the triplet energy level of the green dopant.

### BRIEF DESCRIPTION OF THE DRAWINGS

The accompanying drawings, which are included to provide a further understanding of the disclosure and are incorporated in and constitute a part of this application, illustrate aspect(s) of the disclosure and together with the description serve to explain the principle of the disclosure.

In the drawings:

FIG. 1 is a cross-sectional view showing a white light emitting device according to a first aspect of the present disclosure;

FIG. 2 is a cross-sectional view showing a white light emitting device according to a second aspect of the present disclosure;

FIG. 3 is a graph showing an EL spectrum of the white light emitting device of the present disclosure;

FIG. 4 is a graph showing EL spectrums of first to fourth experimental examples;

FIG. 5 is a diagram showing the blue lifespan in the first to fourth experimental examples;

FIG. 6 is a cross-sectional view showing a light emitting display device according to the present disclosure in connection with a lower driving unit; and

FIG. 7 is a circuit diagram of a subpixel according to an example of the light emitting display device of the present disclosure.

### DETAILED DESCRIPTION

Reference will now be made in detail to exemplary aspects of the present disclosure, examples of which are illustrated in the accompanying drawings. Wherever possible, the same reference numbers will be used throughout the drawings to refer to the same or like parts. In the following description of the present disclosure, a detailed description of known functions and configurations incorporated herein will be omitted when it may obscure the subject matter of the present disclosure. In addition, in the following description of the present disclosure, the names of the elements are selected for ease of explanation, and may be different from actual names.

In the drawings for explaining the exemplary aspects of the present disclosure, for example, the illustrated shape, size, ratio, angle, and number are given by way of example, and thus, are not limited to the disclosure of the present disclosure. Throughout the present specification, the same reference numerals designate the same constituent elements. In addition, in the following description of the present disclosure, a detailed description of known functions and configurations incorporated herein will be omitted when it may make the subject matter of the present disclosure rather unclear. The terms “comprises,” “includes,” and/or “has”, used in this specification, do not preclude the presence or addition of other elements unless used along with the term “only”. The singular forms are intended to include the plural forms as well, unless the context clearly indicates otherwise.

In the interpretation of constituent elements included in the various aspects of the present disclosure, the constituent elements are interpreted as including an error range even if there is no explicit description thereof.

In the description of the various aspects of the present disclosure, when describing positional relationships, for example, when the positional relationship between two parts is described using “on”, “above”, “below”, “next to”, or the like, one or more other parts may be located between the two parts unless the term “directly” or “closely” is used.

In the description of the various aspects of the present disclosure, when describing temporal relationships, for example, when the temporal relationship between two actions is described using “after”, “subsequently”, “next”, “before”, or the like, the actions may not occur in succession unless the term “directly” or “just” is used therewith.

In the description of the various aspects of the present disclosure, although terms such as, for example, “first” and “second” may be used to describe various elements, these terms are merely used to distinguish the same or similar elements from each other. Therefore, in the present specification, an element indicated by “first” may be the same as an element indicated by “second” without exceeding the technical scope of the present disclosure, unless otherwise mentioned.

The respective features of the various aspects of the present disclosure may be partially or wholly coupled to and combined with each other, and various technical linkages and modes of operation thereof are possible. These various aspects may be performed independently of each other, or may be performed in association with each other.

In this specification, the term “doped” means that a material of any layer having physical properties (e.g., N-type and P-type, or an organic material and an inorganic material) different from the material that occupies the greatest weight percentage of the corresponding layer is added to the material accounting for the greatest weight percentage in an amount corresponding to a weight percentage of 30 vol % or less. In other words, a “doped” layer means a layer in which a host material and a dopant material of any layer are distinguishable from each other in consideration of the weight percentages thereof. In addition, the term “undoped” refers to all cases excluding the case that corresponds to the term “doped”. For example, when any layer is formed of a single material or is formed of a mixture of materials having the same or similar properties, the layer is considered an “undoped” layer. In another example, when at least one of constituent materials of any layer is of a P-type and all of the other constituent materials of the layer are not of an N-type, the layer is considered an “undoped” layer. In another example, when at least one of the constituent materials of any layer is an organic material and all of the other constituent materials of the layer are not an inorganic material, the layer is considered an “undoped” layer. In another example, when all constituent materials of any layer are organic materials, at least one of the constituent materials is of an N-type, at least another constituent material is of a P-type, and the weight percent of the N-type material is 30 vol % or less or the weight percent of the P-type material is 30 vol % or less, the layer is considered a “doped” layer.

In this specification, an electroluminescence (EL) spectrum is calculated by multiplying (1) a photoluminescence (PL) spectrum, which applies the inherent characteristics of an emissive material such as a dopant material or a host material included in an organic emission layer, by (2) an outcoupling or emittance spectrum curve, which is determined by the structure and optical characteristics of an organic light-emitting element including the thicknesses of organic layers such as, for example, an electron transport layer.

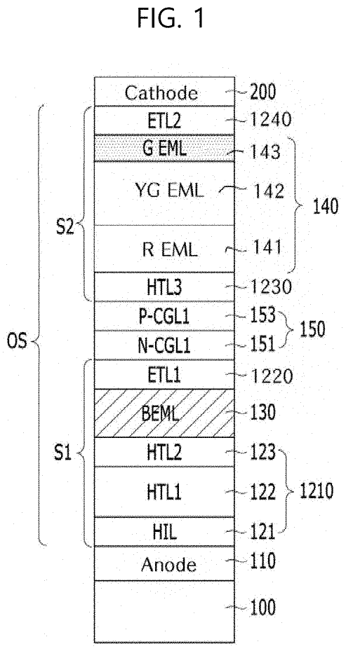

FIG. 1 is a cross-sectional view showing a white light emitting device according to a first aspect of the present disclosure.

As shown in FIG. 1, a white light emitting device according to a first aspect of the present disclosure includes a first electrode 110 and a second electrode 200, which are disposed to be separate apart from each other on a substrate 100, and further includes a charge generation layer 150 disposed between the first electrode 110 and the second electrode 200, a first stack S1 disposed between the first electrode 110 and the charge generation layer 150, and a second stack S2 disposed between the second electrode 200 and the charge generation layer 150.

The first stack S1 is located on the first electrode 110, and includes a first hole-transport-related common layer 1210, a blue emission layer 130, and a first electron-transport-related common layer 1220.

The second stack S2 includes a second hole-transport-related common layer 1230, first to third emission layers 141, 142 and 143, which are sequentially stacked and emit lights, the wavelengths of which are gradually shortened from the first emission layer 141 to the third emission layer 143, and a second electron-transport-related common layer 1240.

Each of the first and second hole-transport-related common layers 1210 and 1230 is a layer related to hole injection and hole transport, and may include at least one of a hole transport layer HTL1, HTL2 or HTL3 or an electron-blocking layer. In addition, the first hole-transport-related common layer 1210 may further include a hole injection layer HIL (121), which is in contact with the first electrode 110 and lowers interfacial resistance when holes are injected from the first electrode 110. Each of the first and second hole-transport-related common layers 1210 and 1230 may be formed as a single layer, or may be formed as multiple layers. As illustrated, the hole-transport-related common layer included in one of the stacks may be formed as multiple layers, and the hole-transport-related common layer included in the other one of the stacks may be formed as a single layer. For example, as shown in FIG. 1, when the first hole-transport-related common layer 1210 of the first stack S1 is formed as multiple layers, the hole transport layer HTL2, which is close to the emission layer 130, may function as an electron-blocking layer that prevents electrons or excitons from escaping from the emission layer 130 to the hole transport layer 122.

Each of the first and second electron-transport-related common layers 1220 and 1240 is a layer related to the transport of electrons and the rate of supply of electrons to an adjacent emission layer, and may include at least one of an electron transport layer ETL1 or ETL2 or a hole-blocking layer. In addition, the second electron-transport-related common layer 1240 may further include an electron injection layer, which is in contact with the second electrode 200 and lowers interfacial resistance when electrons are injected from the second electrode 200. Each of the first and second electron-transport-related common layers 1220 and 1240 may be formed as a single layer, or may be formed as multiple layers.

In the white light emitting device according to the first aspect of the present disclosure, the first stack S1 includes a single blue emission layer 130 to emit blue light. The blue light may have an emission peak within the range from 430 nm to 490 nm. The blue emission layer 130 includes a host and a blue dopant, which emits light by excitation in the host. The blue dopant of the blue emission layer 130 used in the white light emitting device of the present disclosure is a fluorescent dopant. The reason for this is to secure a lifespan similar to that of the long-wavelength phosphorescent emission layers of the second stack S2.

Unlike the first stack S1, the second stack S2 includes a phosphorescent emission unit 140, which is configured such that first to third emission layers 141, 142 and 143 are in contact with each other and emit different lights of longer wavelengths than the wavelength of blue light. Specifically, the first emission layer 141 may be a red emission layer that emits red light, the second emission layer 142 may be a yellowish-green emission layer that emits yellowish-green light, and the third emission layer 143 may be a green emission layer that emits green light. That is, the first emission layer 141 emits light having an emission peak within the range from 590 nm to 650 nm, the second emission layer 142 emits light having an emission peak within the range from 540 nm to 590 nm, and the third emission layer 143 emits light having an emission peak within the range from 510 nm to 560 nm. Among the first to third emission layers 141, 142 and 143 of the second stack S2, the third emission layer 143 emits light of the shortest wavelength. However, the light from the third emission layer 143 has a longer wavelength than the light from the blue emission layer 130. The first to third emission layers 141, 142 and 143 include dopants of different colors in order to emit lights of different colors. For example, the first emission layer 141 includes a red dopant, the second emission layer 142 includes a yellowish-green dopant, and the third emission layer 143 includes a green dopant. Phosphorescent dopants, which have a predetermined efficiency and a predetermined lifespan, may be used as the dopants used for the second stack S2.

The reason why the first to third emission layers 141, 142 and 143, which emit lights of different wavelengths, are provided in the second stack S2 is to enable rich color representation by the light emitting display device. As long as each of the emission layers for emitting lights of various colors does not impair the emission characteristics of other emission layers, as the number of emission layers increases, a color representation effect may be improved, and the color representation range achievable by the light emitting display device may be increased. This means that a great deal of the color representation range achievable by the light emitting display device falls within the range according to the DCI standard or the BT2020 standard.

The emission layers of the second stack S2, which emit lights of long wavelengths, may be implemented as highly efficient phosphorescent emission layers. Because the threshold drive voltage is gradually reduced in the order of the third emission layer 143, the second emission layer 142, and the first emission layer 141, energy not used for excitation in the upper emission layer in the second stack S2 may be used in the lower emission layer. Accordingly, it is possible to increase the efficiency of the second stack S2. To this end, the first to third emission layers 141, 142 and 143 are formed such that the wavelengths of the lights emitted therefrom are gradually increased in the order of the third emission layer 143, the second emission layer 142, and the first emission layer 141 so that the threshold drive voltage is gradually reduced in that order. In the aspect shown in FIG. 1, the first emission layer 141 is a red emission layer, the second emission layer 142 is a yellowish-green emission layer, and the third emission layer 143 is a green emission layer.

Each of the blue emission layer 130 and the first to third emission layers 141, 142 and 143 includes a host and a dopant. One or multiple hosts may be provided in each emission layer as needed.

The blue emission layer 130 includes a fluorescent dopant, and each of the first to third emission layers 141, 142 and 143 includes a phosphorescent dopant, which has relatively high efficiency. The phosphorescent dopant of each of the first to third emission layers 141, 142 and 143 is a metal complex compound including iridium (Ir), platinum (Pt), osmium (Os), gold (Au), titanium (Ti), zirconium (Zr), hafnium (Hf), europium (Eu), terbium (Tb), palladium (Pd), or thulium (Tm). The host of each of the first to third emission layers 141, 142 and 143 may include a host having electron transport capability and/or a host having hole transport capability. The phosphorescent dopants of the first to third emission layers 141, 142 and 143 have a difference in triplet level T1 required for excitation.

Meanwhile, in the white light emitting device of the present disclosure, both the triplet energy level T1 of the phosphorescent dopants and the triplet energy level T1 of the blue dopant, which is a fluorescent dopant, are considered. For reference, the fluorescent dopant emits fluorescent light while transition from a singlet energy level S1 to a ground state occurs.

The triplet energy level T1 of each material described herein is measured at an extremely low temperature, for example, the absolute temperature of 77 K in a liquid nitrogen environment. That is, in order to examine the triplet level characteristics of each material, light is radiated thereto in the state in which a strong electric field is applied thereto at the absolute temperature of 77 K, and light emitted therefrom is measured in the delay time of 1 μs after the formation of an excited state. The light emitted after the application of a strong electric field is measured, and the triplet energy level T1 is calculated using the following wavelength conversion formula: T1(eV)=1240/λa. Here, when a tangent line is drawn at a point on the first rising short-wavelength curve of a phosphorescent spectrum in a coordinate system in which the x-axis represents the wavelength and the y-axis represents the phosphorescent spectrum, λa is the value of the wavelength at the intersection of the tangent line and the x-axis.

In the white light emitting device of the present disclosure, the triplet energy level T1 of the blue dopant is defined in relation to the triplet energy levels T1 of the dopants in the emission layers of other colors.

The triplet energy level of the blue dopant T1(BD), the triplet energy level of the red dopant T1(RD), the triplet energy level of the yellowish-green dopant T1(YGD), and the triplet energy level of the green dopant T1(GD) have the following relationship therebetween: T1(BD)≥T1(GD>T1(YGD)>T1(RD).

That is, in the white light emitting device of the present disclosure, the triplet energy level T1(BD) of the first blue dopant BD may be equal to or higher than the triplet energy level T1(GD) of the green dopant.

Further, in the second stack S2, the triplet energy level T1(GD) of the green dopant may be higher than the triplet energy level T1(YGD) of the yellowish-green dopant, and the triplet energy level T1(YGD) of the yellowish-green dopant may be higher than the triplet energy level T1(RD) of the red dopant.

As described above, the measurement of the value of the triplet energy level of each dopant material is performed by measuring a phosphorescent excited state in a predetermined delay time at an extremely low temperature. The value of the triplet energy level is obtained in inverse proportion to the measured wavelength. However, because the value of the triplet energy level is measured at an extremely low temperature, unlike general phosphorescent emission at room temperature, the value of the triplet energy level exhibits characteristics different from the emission characteristics of the emission dopants.

In particular, since the blue dopant, which is used as a fluorescent dopant, is not excited to phosphorescence in the emission layer, the value of the triplet energy level of the blue fluorescent dopant is not directly considered as a factor for emission. The inventors of the present disclosure compared the triplet level characteristics of the blue dopant (fluorescence) with the triplet level characteristics of the dopants of other colors, which are located in other stacks, and obtained the relationship therebetween that is capable of securing high efficiency.

The inventors of the present disclosure have experimentally confirmed that the efficiency of blue light emission is increased when the triplet energy level T1(BD) of the blue dopant is higher than at least the triplet energy level T1(GD) of the green dopant.

Meanwhile, in order to maximize extraction of phosphorescent light, the first to third emission layers 141, 142 and 143 are arranged in the second stack S2 such that the emission layer emitting light of the longest wavelength is located closest to the light extraction surface. For example, in the case of a bottom emission-type display device, the first emission layer 141 is a red emission layer, the second emission layer 142 is a yellowish-green emission layer, and the third emission layer 143 is a green emission layer.

In addition, the triplet energy levels T1 of the dopants of the emission layers are sequentially arranged so as to make a device that enables electrically smooth hole injection. That is, the red emission layer, the yellowish-green emission layer, and the green emission layer are sequentially arranged such that the red emission layer is located closest to the first electrode 110, which is an electrode from which light is extracted. That is, in the second stack S2, the triplet energy level T1(GD) of the green dopant may be greater than the triplet energy level T1(YGD) of the yellowish-green dopant, and the triplet energy level T1(YGD) of the yellowish-green dopant may be greater than the triplet energy level T1(RD) of the red dopant. In the case of T1(GD)>T1(YGD)>T1(RD), it is possible to implement a device that enables electrically smooth hole injection.

The result of experiments performed while varying the relationship between the triplet energy levels of the dopants will be described later.

As illustrated, the charge generation layer 150 located between the stacks S1 and S2 may include an n-type charge generation layer 151 and a p-type charge generation layer 153. Alternatively, the charge generation layer 150 may be formed as a single layer in which an n-type dopant and a p-type dopant are included in a single host.

The first electrode 110 may function as an anode, and the second electrode 200 may function as a cathode. The first electrode 110 may include a transparent electrode, and the second electrode 200 may include a reflective electrode.

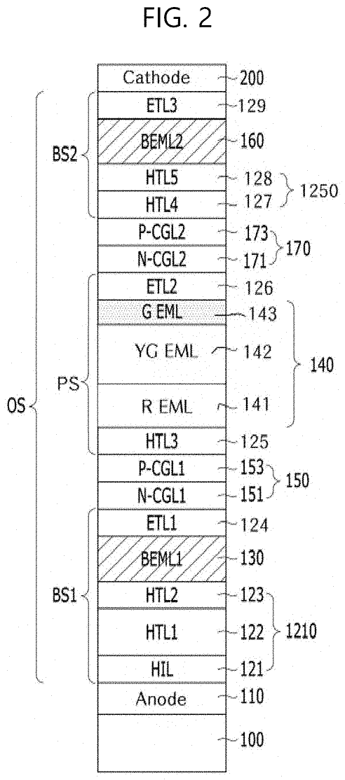

FIG. 2 is a cross-sectional view showing a white light emitting device according to a second aspect of the present disclosure.

As shown in FIG. 2, the white light emitting device according to the second aspect of the present disclosure includes a phosphorescent stack PS, which includes first to third emission layers 141, 142 and 143, a first blue emission stack BS1, which is located under the phosphorescent stack PS and emits blue light, and a second blue emission stack BS2, which is located on the phosphorescent stack PS and emits blue light. That is, the white light emitting device according to the second aspect differs from the first aspect in that multiple blue emission stacks are provided in order to increase the efficiency of blue color emission, which is insufficient compared to the phosphorescent stack PS.

In addition, a charge generation layer 150 is provided between the first blue emission stack BS1 and the phosphorescent stack PS, and a charge generation layer 170 is provided between the second blue emission stack BS2 and the phosphorescent stack PS. As illustrated, the charge generation layer 150 may include an n-type charge generation layer 151 and a p-type charge generation layer 153 stacked on the n-type charge generation layer 151, and the charge generation layer 170 may include an n-type charge generation layer 171 and a p-type charge generation layer 173 stacked on the n-type charge generation layer 171. Alternatively, each of the charge generation layers 150 and 170 may be formed as a single layer in which an n-type dopant and a p-type dopant are included in a single host.

Although a single subpixel is illustrated in FIG. 2, the first electrode 110 may be patterned corresponding to a plurality of subpixels so as to be divided for each subpixel. The organic stack OS, which is located on the first electrode 110, and the second electrode 200 may be formed continuously over the plurality of subpixels without breaks therein.

In the white light emitting device according to the second aspect of the present disclosure, the first electrode 110 is divided for each subpixel, but each of the components disposed thereon is formed in a unitary body in at least the display area, without using a fine metal mask. Accordingly, in the white light emitting device according to the second aspect of the present disclosure, the use of a fine metal mask may be omitted after the formation of the first electrode 110, whereby it is possible to improve processability and to alleviate a decrease in yield that may be caused by misalignment of masks. In addition, in the white light emitting device according to the second aspect of the present disclosure, lights of different colors emitted from the multiple stacks S1 and S2 (or BS1, PS and BS2) may be combined to generate white light, and the subpixels may emit lights of different colors to color filters 109R, 109G and 109B (shown in FIG. 6), which are provided at emission sides of respective subpixels.

The first blue emission stack BS1 is located on the first electrode 110, and includes a first hole-transport-related common layer 1210, a first blue emission layer BEML1 (130), and a first electron-transport-related common layer 124.

The second stack S2 (or a phosphorescent stack PS) includes a second hole-transport-related common layer 125, first to third emission layers 141, 142 and 143, which are sequentially stacked and emit lights, the wavelengths of which are gradually shortened from the first emission layer 141 to the third emission layer 143, and a second electron-transport-related common layer 126.

The second blue emission stack BS2 includes a third hole-transport-related common layer 1250, a second blue emission layer BEML2 (160), and a third electron-transport-related common layer 129.

Similar to the first blue emission stack BS1, the third hole-transport-related common layer 1250 may include a plurality of hole transport layers 127 and 128. The hole transport layer HTL5 (128), which is located on the hole transport layer HTL4 (127), may function as an electron-blocking layer.

The first electrode 110 may include a transparent electrode, and the second electrode 200 may include a reflective electrode, so the light generated by the organic stack OS may be emitted through the first electrode 110.

The second electrode 200 may be formed such that multiple layers are stacked one on another. Among the multiple layers, the layer that is in contact with the organic stack OS may be formed of an inorganic compound including metal and a halogen material such as fluorine, and may function as an electron injection layer. When an electron injection layer is formed of an inorganic material or an inorganic compound, the electron injection layer may be formed in a different chamber from the organic stack OS, and may be formed using the same mask and/or in the same chamber as the second electrode 200.

As described above, each of the first and second aspects includes the phosphorescent stack S2 or PS having the phosphorescent unit 140, in which multiple phosphorescent emission layers are sequentially stacked.

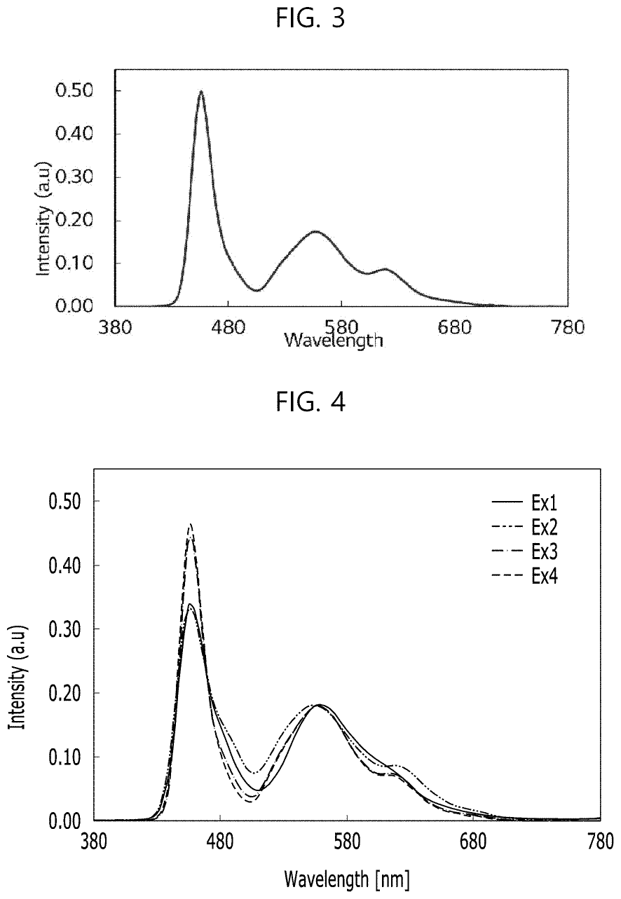

FIG. 3 is a graph showing an EL spectrum of the white light emitting device of the present disclosure.

Referring to the EL spectrum of the white light emitting device of the present disclosure shown in FIG. 3, the emission intensity is approximately 0.17 at the peak wavelength of the phosphorescent emission stack, and the emission intensity is approximately 0.464 at the peak wavelength of the blue stack. That is, the blue emission intensity is approximately 2.6 times the emission intensity of the phosphorescent emission stack. Accordingly, it is possible to increase the efficiency of blue light emission of relatively low visibility and thus to improve both emission efficiency and color temperature. The improvement of the color temperature means that rich color representation is possible, visibility is improved, and eye-friendly cool white light is realized.

That is, the white light emitting device of the present disclosure uses the blue dopant, which has a high triplet energy level that is equivalent to the triplet energy level of the green dopant, in the blue emission layer, thereby improving the efficiency of the white light emitting device and improving the color temperature.

Hereinafter, the result of experiments performed on the structure shown in FIG. 2 while varying the relationship between the triplet energy levels of the blue dopant BD of the blue emission layer, the green dopant GD of the green emission layer, the yellowish-green dopant of the yellowish-green emission layer, and the red dopant of the red emission layer will be described with reference to Table 1 below.

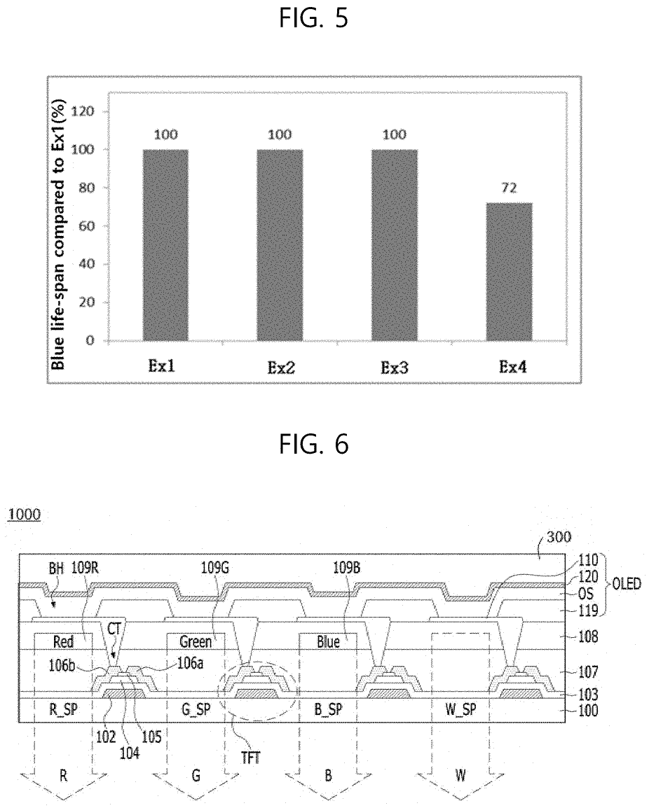

FIG. 4 is a graph showing the EL spectrums of first to fourth experimental examples Ex1, Ex2, Ex3 and Ex4, and FIG. 5 is a diagram showing the blue lifespan in the first to fourth experimental examples Ex1, Ex2, Ex3 and Ex4.

TABLE 1

| | | | | | Blue | Color |
|---|---|---|---|---|---|---|
| | T1(BD) | T1(GD) | T1(YGD) | T1(RD) | Intensity | Temperature |
| | [eV] | [eV] | [eV] | [eV] | [a.u.] | [K] |
| Ex1 | 2.0 | 2.4 | 2.2 | 2.0 | 0.340 | ≈7000 |
| Ex2 | 2.0 | 2.4 | 2.3 | 2.0 | 0.332 | ≈7000 |
| Ex3 | 2.4 | 2.4 | 2.3 | 2.0 | 0.443 | >8000 |
| Ex4 | 2.8 | 2.4 | 2.3 | 2.0 | 0.464 | >8000 |

In the first experimental example Ex1, the triplet energy level T1(BD) of the blue dopant is 2.0 eV, and the triplet energy level T1(GD) of the green dopant is 2.4 eV. That is, a material exhibiting the triplet energy level higher than the triplet energy level T1(BD) of the blue dopant is used for the green dopant. Further, in the first experimental example, the triplet energy level T1(YGD) of the yellowish-green dopant is 2.2 eV, and the triplet energy level T1(RD) of the red dopant is 2.0 eV. In this case, all of the phosphorescent dopants have triplet energy levels higher than the triplet energy level of the blue (fluorescent) dopant. In this case, as shown in Table 1 and FIG. 4, the blue emission intensity is 0.340, and the color temperature of the device is approximately 7000 K.

In the second experimental example Ex2, the triplet energy level T1(BD) of the blue dopant is 2.0 eV, and the triplet energy level T1(GD) of the green dopant is 2.4 eV. Further, in the second experimental example Ex2, the triplet energy level T1(YGD) of the yellowish-green dopant is 2.3 eV, and the triplet energy level T1(RD) of the red dopant is 2.0 eV. In this case, all of the phosphorescent dopants have triplet energy levels higher than the triplet energy level of the blue (fluorescent) dopant. Furthermore, compared to the first experimental example Ex1, the triplet energy level T1(YGD) of the yellowish-green dopant is increased by changing the material thereof. In the second experimental example Ex2, as shown in Table 1 and FIG. 4, the blue emission intensity is 0.332, and the color temperature of the device is approximately 7000 K.

In the third experimental example Ex3, the triplet energy level T1(BD) of the blue dopant is 2.4 eV, and the triplet energy level T1(GD) of the green dopant is 2.4 eV. Further, in the third experimental example Ex3, the triplet energy level T1(YGD) of the yellowish-green dopant is 2.3 eV, and the triplet energy level T1(RD) of the red dopant is 2.0 eV. That is, the triplet energy level T1(BD) of the blue dopant and the triplet energy level T1(GD) of the green dopant are equal or similar to each other, and are higher than the triplet energy levels T1(YGD) and T1(RD) of the remaining phosphorescent dopants YG and R. Accordingly, the blue emission intensity is 0.443, and the color temperature exceeds 8000 K. As a result, the blue emission intensity is increased by 30% compared to the blue emission intensities in the first and second experimental examples Ex1 and Ex2, and the color temperature is improved by 14% or more compared to the color temperatures in the first and second experimental examples Ex1 and Ex2.

In the fourth experimental example Ex4, the triplet energy level T1(BD) of the blue dopant is 2.8 eV, and the triplet energy level T1(GD) of the green dopant is 2.4 eV. Further, in the fourth experimental example Ex4, the triplet energy level T1(YGD) of the yellowish-green dopant is 2.3 eV, and the triplet energy level T1(RD) of the red dopant is 2.0 eV. That is, the triplet energy level T1(BD) of the blue dopant is higher than the triplet energy level T1(GD) of the green dopant. Accordingly, the blue emission intensity is 0.0464, and the color temperature of the device exceeds 8000 K. As a result, both the efficiency of blue light emission and the color temperature of the device are improved.

Meanwhile, it can be seen from FIG. 4 that the third and fourth experimental examples Ex3 and Ex4 according to the structure of the white light emitting device of the present disclosure exhibit greatly increased efficiency of blue light emission.

FIG. 5 shows the remaining lifespans of the first to fourth experimental examples Ex1, Ex2, Ex3 and Ex4 when the brightness is reduced to 95% of the initial brightness under the conditions that the emission layers having the triplet energy levels T1 described in the first to fourth experimental examples Ex1, Ex2, Ex3 and Ex4 are applied to the structure shown in FIG. 2, the temperature is 40° C., and the current density is 40 mA/cm2. In this case, the remaining lifespans of the first to third experimental examples Ex1, Ex2 and Ex3 are identical to each other, and the remaining lifespan of the fourth experimental example Ex4 is relatively short. As described above, the efficiency of blue light emission in the third and fourth experimental examples Ex3 and Ex4 is improved by 30% or more compared to that in the first experimental example Ex1. If the first experimental example Ex1 and the fourth experimental example Ex4 are made to have the same brightness, it is possible to reduce the drive voltage of the fourth experimental example Ex4 because the fourth experimental example Ex4 is highly efficient. Accordingly, it can be inferred that the lifespan of the fourth experimental example Ex4 is capable of being increased to that of the first experimental example Ex1 or more by reducing the drive voltage of the fourth experimental example Ex4.

Meanwhile, the blue dopant used in the above-described experimental examples may be a boron-based dopant having boron as a core, and may have, for example, any of the configurations shown in Formulas 1 to 3 below. The present disclosure requires a blue dopant having a relatively high triplet energy level. To this end, it is possible to adjust the value of the triplet energy level T1 by controlling components introduced into an end group or a substituent in a boron-based compound.

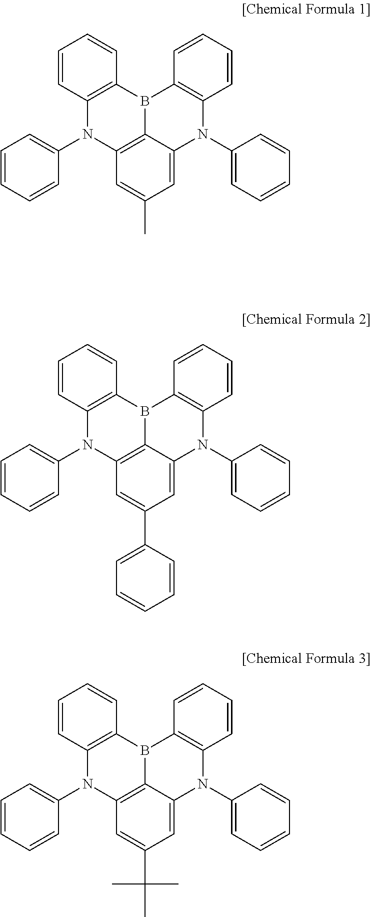 [SMILES: Cc1cc2c3c(c1)N(c1ccccc1)c1ccccc1B3c1ccccc1N2c1ccccc1 ; c1ccc(-c2cc3c4c(c2)N(c2ccccc2)c2ccccc2B4c2ccccc2N3c2ccccc2)cc1 ; CC(C)(C)c1cc2c3c(c1)N(c1ccccc1)c1ccccc1B3c1ccccc1N2c1ccccc1]

Meanwhile, the green dopant, the yellowish-green dopant, and the red dopant, which are phosphorescent dopants, are heavy metal complex compounds. For example, the green dopant and the yellowish-green dopant may have the configuration shown in Formula 4, and the red dopant may have the configuration shown in Formula 5. It is possible to adjust the wavelength by controlling components of the substituents of the green dopant and the yellowish-green dopant.

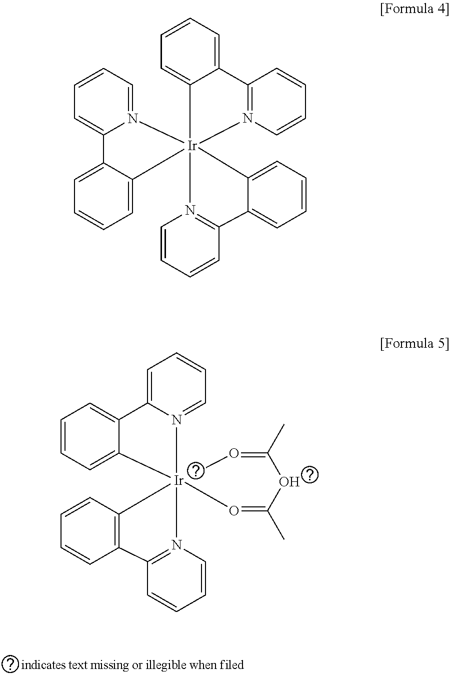

Although it is illustrated that iridium (Ir) is used as an example of the green dopant, the yellowish-green dopant, and the red dopant, the aspect is not limited thereto. An example of heavy metal elements may be a metal complex compound including iridium (Ir), platinum (Pt), osmium (Os), gold (Au), titanium (Ti), zirconium (Zr), hafnium (Hf), europium (Eu), terbium (Tb), palladium (Pd), or thulium (Tm). However, the aspect is not limited thereto. The heavy metal element may be replaced by another core heavy metal as needed.

As described above, in the white light emitting device of the present disclosure, the triplet energy levels of the dopants in the emission layers have the following relationship therebetween: T1(BD)?T1(GD)>T1(YGD)>T1(RD). Accordingly, it is possible to improve the efficiency of blue light emission and to increase the color temperature, thereby enabling more vivid and stable color representation.

That is, according to the white light emitting device of the present disclosure, although the blue emission layer is located in a different stack from the phosphorescent emission layer, it is possible to improve the efficiency of the device by appropriately adjusting the relationship between the triplet energy level of the blue dopant in the blue emission layer of the blue emission stack and the triplet energy levels of the phosphorescent dopants in the phosphorescent emission layer. Accordingly, it is possible to greatly improve the efficiency of blue light emission in the light emitting device and the display device. Further, it is possible to ensure long-term use of the blue fluorescent dopant and to increase the efficiency thereof without the necessity to use a blue phosphorescent dopant, which is difficult to use due to the short lifespan thereof.

In addition, in the white light emitting device of the present disclosure, the triplet energy level of the blue dopant is made to be equal to or higher than the triplet energy level of the green dopant, thereby increasing the efficiency of blue light emission, thus increasing the color temperature and enabling rich color representation. As a result, it is possible to realize cool white light and to secure stable and improved visibility.

Hereinafter, the light emitting display device of the present disclosure will be described in connection with the configurations of the white light emitting device described above, thin-film transistors, and color filters.

FIG. 6 is a cross-sectional view showing a light emitting display device according to the present disclosure.

As shown in FIG. 6, a light emitting display device 1000 of the present disclosure includes an organic stack OS provided between a first electrode 110 and a second electrode 120 (shown as 200 in FIGS. 1 and 2), and the organic stack OS includes at least one blue emission stack S1 or BS1/BS2 and a phosphorescent emission stack S2 or PS in which multiple phosphorescent emission layers are stacked (shown in FIG. 1 or FIG. 2). A charge generation layer is provided between the blue emission stack and the phosphorescent emission stack. In addition, a hole-transport-related common layer and an electron-transport-related common layer are respectively provided under and on a blue emission layer B EML or B EML1/B EML2 of the blue emission stack S1 or BS1/BS2. The phosphorescent emission stack includes a phosphorescent emission unit 140. The phosphorescent emission unit 140 includes first to third emission layers 141, 142 and 143, which emit lights, the wavelengths of which are gradually shortened from the first emission layer 141 to the third emission layer 143. A hole-transport-related common layer and an electron-transport-related common layer are respectively provided under and on the phosphorescent emission unit 140.

Each subpixel emits white light through the organic stack OS provided between the first electrode 110 and the second electrode 120. Color filters 109R, 109G and 109B are provided at emission sides of respective subpixels in order to emit light of different colors.

In the illustrated example, a thin-film transistor array is provided at the emission side. The light from the first electrode 110 passes through the substrate 100 via the color filters 109R, 109G and 109B.

The display device of the present disclosure may include a substrate 100, which has a plurality of subpixels R_SP, G_SP, B_SP and W_SP, a white light emitting device OLED (refer to FIGS. 1 and 2), which is commonly provided in the subpixels R_SP, G_SP, B_SP and W_SP of the substrate 100, a thin-film transistor TFT, which is provided in each of the subpixels and is connected to the first electrode 110 of the white light emitting device OLED, and color filter layers 109R, 109G and 109B, which are provided under the first electrode 110 of at least one of the subpixels.

Although the display device is illustrated as including the white subpixel W_SP, the aspect is not limited thereto. The white subpixel W_SP may be omitted, and only the red, green and blue subpixels R_SP, G_SP and B_SP may be included. In some cases, the red, green and blue subpixels may be replaced by a cyan subpixel, a magenta subpixel, and a yellow subpixel, which are capable of expressing white in combination.

The thin-film transistor TFT includes, for example, a gate electrode 102, a semiconductor layer 104, a source electrode 106a, which is connected to one side of the semiconductor layer 104, and a drain electrode 106b, which is connected to the opposite side of the semiconductor layer 104.

A gate insulation film 103 is provided between the gate electrode 102 and the semiconductor layer 104.

The semiconductor layer 104 may be formed of a material selected from the group consisting of amorphous silicon, polycrystalline silicon, an oxide semiconductor, and combinations thereof. For example, when the semiconductor layer 104 is formed of an oxide semiconductor, a channel protection layer 105 may be further provided so as to be in direct contact with the upper surface of the semiconductor layer 104 in order to prevent damage to a channel portion of the semiconductor layer 104.

In addition, the drain electrode 106b of the thin-film transistor TFT may be connected to the first electrode 110 in the region of a contact hole CT, which is formed in first and second protective films 107 and 108.

The first protective film 107 is provided to primarily protect the thin-film transistor TFT. The color filter layers 109R, 109G and 109B may be provided on the first protective film 107.

When the plurality of subpixels SP includes a red subpixel R_SP, a green subpixel G_SP, a blue subpixel B_SP, and a white subpixel W_SP, each of the first to third color filter layers 109R, 109G and 109B is provided in a corresponding one of the subpixels other than the white subpixel W_SP so as to transmit white light, having passed through the first electrode 110, for each wavelength. The second protective film 108 is formed under the first electrode 110 so as to overlay the first to third color filter layers 109R, 109G and 109B. The first electrode 110 is formed on the surface of the second protective film 108 except for the contact hole CT.

Here, the white light emitting device OLED includes the organic stack OS between the first electrode 110, which is transparent, and the second electrode 120, which is disposed opposite the first electrode 110 and is reflective, and emits light through the first electrode 110.

Here, reference numeral 119 represents a bank, and “BH” between the banks represents a bank hole. Light emission is performed in a region that is open through the bank hole. The bank hole defines an emission portion of each subpixel.

The display device shown in FIG. 6 is a bottom emission-type display device. However, the present disclosure is not limited to a bottom emission-type display device. The display device of the present disclosure may be implemented as a top emission-type display device by changing the structure shown in FIG. 6 such that the color filter layers are located on the second electrode 120, such that reflective metal is included in the first electrode 110, and such that the second electrode 120 is formed as a transparent electrode or is formed of semi-transmissive metal.

Alternatively, the color filter layers may be omitted, and both the first electrode 110 and the second electrode 120 may be formed as transparent electrodes, thereby implementing a transparent organic light emitting device.

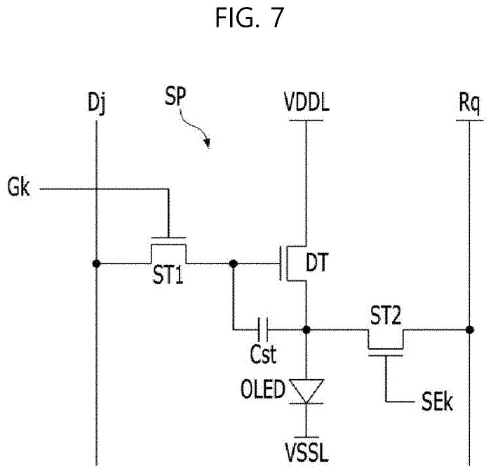

As shown in FIG. 7, each of the subpixels SP may include a white light emitting device OLED, a driving transistor DT, a plurality of switching transistors, and a capacitor Cst. The plurality of switching transistors may include first and second switching transistors ST1 and ST2. For convenience of description, FIG. 7 illustrates only a pixel P that is connected to a j^{th} data line Dj (j is an integer of two or more), a q^{th} reference voltage line Rq (q is an integer of two or more), a k^{th} gate line Gk (k is an integer of two or more), and a k^{th} initialization line SEk.

The white light emitting device OLED emits light with a current supplied through the driving transistor DT. A first electrode of the white light emitting device OLED may be connected to a source electrode of the driving transistor DT, and a second electrode of the white light emitting device OLED may be connected to a first power voltage line VSSL through which a first power voltage is supplied. The first power voltage line VSSL may be a low-level voltage line through which a low-level power voltage is supplied.

The driving transistor DT is disposed between the white light emitting device OLED and a second power voltage line VDDL through which a second power voltage is supplied. The driving transistor DT controls the current flowing from the second power voltage line VDDL to the white light emitting device OLED, based on a voltage difference between a gate electrode and a source electrode of the driving transistor DT. The gate electrode of the driving transistor DT may be connected to a first electrode of the first switching transistor ST1, the source electrode of the driving transistor DT may be connected to the second power voltage line VDDL, and a drain electrode of the driving transistor DT may be connected to the first electrode of the white light emitting device OLED. The second power voltage line VDDL may be a high-level voltage line through which a high-level power voltage is supplied.

The first switching transistor ST1 may be turned on by a k^{th} gate signal of the k^{th} gate line Gk and may supply the voltage of the j^{th} data line Dj to the gate electrode of the driving transistor DT. A gate electrode of the first switching transistor ST1 may be connected to the k^{th} gate line Gk, a source electrode of the first switching transistor ST1 may be connected to the gate electrode of the driving transistor DT, and a drain electrode of the first switching transistor ST1 may be connected to the j^{th} data line Dj.

The second switching transistor ST2 may be turned on by a k^{th} initialization signal of the k^{th} initialization line SEk and may connect the q^{th} reference voltage line Rq to the drain electrode of the driving transistor DT. A gate electrode of the second switching transistor ST2 may be connected to the k^{th} initialization line SEk, a first electrode of the second switching transistor ST2 may be connected to the q^{th} reference voltage line Rq, and a second electrode of the second switching transistor ST2 may be connected to the drain electrode of the driving transistor DT.

The capacitor Cst is formed between the gate electrode and the source electrode of the driving transistor DT. The capacitor Cst stores a differential voltage between a gate voltage and a source voltage of the driving transistor DT.

One electrode of the capacitor Cst may be connected to the gate electrode of the driving transistor DT and the source electrode of the first switching transistor ST1, and the other electrode of the capacitor Cst may be connected to the source electrode of the driving transistor DT, the drain electrode of the second switching transistor ST2, and the first electrode of the white light emitting device OLED.

The driving transistor DT, the first switching transistor ST1, and the second switching transistor ST2 of each of the subpixels P may be formed as thin-film transistors. Although it is illustrated in FIG. 3 that the driving transistor DT, the first switching transistor ST1, and the second switching transistor ST2 of each of the subpixels P are formed as N-type semiconductor transistors having N-type semiconductor characteristics, the aspects of the present disclosure are not limited thereto. That is, the driving transistor DT, the first switching transistor ST1, and the second switching transistor ST2 of each of the subpixels P may be formed as P-type semiconductor transistors having P-type semiconductor characteristics.

A white light emitting device according to one aspect of a present disclosure may comprise a first electrode and a second electrode facing each other on a substrate, a first stack disposed between the first electrode and a first charge generation layer, the first stack comprising a first emission layer including a first blue dopant and a second stack disposed between the first charge generation layer and the second electrode, the second stack comprising a second emission layer including a red dopant, a third emission layer including a yellowish-green dopant, and a fourth emission layer including a green dopant. The first blue dopant may have a triplet energy level equal to or higher than a triplet energy level of the green dopant.

In the second stack, the triplet energy level of the green dopant may be higher than a triplet energy level of the yellowish-green dopant, and the triplet energy level of the yellowish-green dopant may be higher than a triplet energy level of the red dopant.

The first blue dopant may be a fluorescent dopant, and the red dopant, the yellowish-green dopant, and the green dopant may be phosphorescent dopants.

The first blue dopant may be a boron-based compound.

In some cases, the first blue dopant may a fluorescent dopant, and the green dopant is phosphorescent dopant.

The white light emitting device may further comprise a second charge generation layer and a third stack provided on the second stack, the third stack comprising a fifth emission layer to emit light of a same color as the first emission layer.

The fifth emission layer may include a second blue dopant same as the first blue dopant.

A light emitting display device according to one aspect of a present disclosure may comprise a substrate comprising a plurality of subpixels, a first electrode at each of the plurality of subpixels on the substrate, a second electrode over the plurality of subpixels to be opposite the first electrode, a first stack between the first electrode and a first charge generation layer over the plurality of subpixels, the first stack comprising a first emission layer including a first blue dopant and a second stack between the first charge generation layer and the second electrode over the plurality of subpixels, the second stack comprising a second emission layer including a red dopant, a third emission layer including a yellowish-green dopant, and a fourth emission layer including a green dopant. The first blue dopant may have a triplet energy level equal to or higher than a triplet energy level of the green dopant.

In the second stack, the triplet energy level of the green dopant may be higher than a triplet energy level of the yellowish-green dopant, and the triplet energy level of the yellowish-green dopant may be higher than a triplet energy level of the red dopant.

The first blue dopant may be a fluorescent dopant, and wherein the red dopant, the yellowish-green dopant, and the green dopant may be phosphorescent dopants.

The first blue dopant may be a boron-based compound.

The light emitting display device may further comprise a second charge generation layer and a third stack provided on the second stack, the third stack comprising a fifth emission layer to emit light of the same color as the first emission layer.

The fifth emission layer may include a second blue dopant same as the first blue dopant.

The light emitting display device may further comprise a color filter layer and a thin-film transistor between the substrate and the first electrode, the thin-film transistor being connected to the first electrode.

As is apparent from the above description, the white light emitting device and the light emitting display device including the same according to the present disclosure have the following effects.

First, although the blue emission layer is located in a different stack from the phosphorescent emission layer, it is possible to improve the efficiency of the device by appropriately adjusting the relationship between the triplet energy level of the blue dopant in the blue emission layer of the blue emission stack and the triplet energy levels of the phosphorescent dopants in the phosphorescent emission layer. Accordingly, it is possible to greatly improve the efficiency of blue light emission in the light emitting device and the display device. Further, it is possible to ensure long-term use of the blue fluorescent dopant and to increase the efficiency thereof without the necessity to use a blue phosphorescent dopant, which is difficult to use due to the short lifespan thereof.

Second, the triplet energy level of the blue dopant is made to be equal to or higher than the triplet energy level of the green dopant, thereby increasing the efficiency of blue light emission, thus increasing the color temperature and enabling rich color representation. As a result, it is possible to realize cool white light and to secure stable and improved visibility.

It will be apparent to those skilled in the art that various modifications and variations can be made in the present disclosure without departing from the spirit or scope of the disclosure. Thus, it is intended that the present disclosure covers the modifications and variations of this disclosure provided they come within the scope of the appended claims and their equivalents.

What is claimed is:

1. A white light emitting device comprising:
a first electrode and a second electrode facing each other over a substrate;
a first stack disposed between the first electrode and a first charge generation layer and including a first emission layer having a first blue dopant; and
a second stack disposed between the first charge generation layer and the second electrode, the second stack comprising a second emission layer including a red dopant, a third emission layer including a yellowish-green dopant, and a fourth emission layer including a green dopant,
wherein the first blue dopant has a triplet energy level equal to or higher than a triplet energy level of the green dopant.

2. The white light emitting device according to claim 1, wherein the triplet energy level of the green dopant is higher than a triplet energy level of the yellowish-green dopant, and the triplet energy level of the yellowish-green dopant is higher than a triplet energy level of the red dopant.

3. The white light emitting device according to claim 1, wherein the first blue dopant is a fluorescent dopant, and the red dopant, the yellowish-green dopant and the green dopant include a phosphorescent dopant.

4. The white light emitting device according to claim 1, wherein the first blue dopant includes a boron-based compound.

5. The white light emitting device according to claim 1, wherein the first blue dopant includes a fluorescent dopant, and the green dopant includes a phosphorescent dopant.

6. The white light emitting device according to claim 1, further comprising a second charge generation layer and a third stack provided on the second stack, the third stack comprising a fifth emission layer to emit light of a same color as the first emission layer.

7. The white light emitting device according to claim 6, wherein the fifth emission layer includes a second blue dopant that is the same as the first blue dopant.

8. A light emitting display device comprising:
a substrate comprising a plurality of subpixels;
a first electrode at each of the plurality of subpixels on the substrate;
a second electrode disposed over the plurality of subpixels to be opposite to the first electrode;
a first stack between the first electrode and a first charge generation layer over the plurality of subpixels, and including a first emission layer having a first blue dopant; and
a second stack between the first charge generation layer and the second electrode over the plurality of subpixels, and including a second emission layer including a red dopant, a third emission layer including a yellowish-green dopant, and a fourth emission layer including a green dopant,
wherein the first blue dopant has a triplet energy level equal to or higher than a triplet energy level of the green dopant.

9. The light emitting display device according to claim 8, wherein, the triplet energy level of the green dopant is higher than a triplet energy level of the yellowish-green dopant, and the triplet energy level of the yellowish-green dopant is higher than a triplet energy level of the red dopant.

10. The light emitting display device according to claim 8, wherein the first blue dopant includes a fluorescent dopant, and the red dopant and the yellowish-green dopant and the green dopant include a phosphorescent dopant.

11. The light emitting display device according to claim 8, wherein the first blue dopant includes a boron-based compound.

12. The light emitting display device according to claim 8, wherein the first blue dopant includes a fluorescent dopant, and the green dopant includes a phosphorescent dopant.

13. The light emitting display device according to claim 8, further comprising a second charge generation layer and a third stack provided on the second stack,
wherein the third stack includes a fifth emission layer to emit light of a same color as the first emission layer.

14. The light emitting display device according to claim 13, wherein the fifth emission layer includes a second blue dopant that is the same as the first blue dopant.

15. The light emitting display device according to claim 8, further comprising a color filter layer and a thin-film transistor between the substrate and the first electrode, wherein the thin-film transistor is connected to the first electrode.

16. A white light emitting device comprising:
an anode electrode and a cathode electrode spaced apart from each other;
a first hole-transport-related common layer disposed on the anode electrode;
a blue emission layer including a first blue dopant and disposed on the first hole-transport-related common layer;
a first electron-transport-related common layer disposed on the blue emission layer;
a first charge generation layer disposed on the first electron-transport-related common layer;
a second hole-transport-related common layer disposed on the first charge generation layer; and
first, second emission layers disposed between the first charge generation layer and the cathode layer and respectively including a red dopant, a yellowish-green dopant and a green dopant,
wherein the first blue dopant has a triplet energy level equal to or higher than the green dopant, the green dopant has a higher triplet energy level than the yellowish-green dopant, and the yellowish-green dopant has a higher triplet energy level than the red dopant.

17. The white light emitting device according to claim 16, wherein the first blue dopant is a fluorescent dopant, and the red dopant, the yellowish-green dopant and the green dopant include a phosphorescent dopant.

18. The white light emitting device according to claim 16, wherein the first blue dopant includes a boron-based compound.

19. The white light emitting device according to claim 16, wherein the first blue dopant includes a fluorescent dopant, and the green dopant includes a phosphorescent dopant.

20. The white light emitting device according to claim 1, further comprising a second charge generation layer and a fifth emission layer to emit light of a same color as the first emission layer.
